(19) United States
(12) Patent Application Publication
(10) Pub. No.: US 2026/0040556 A1
(43) Pub. Date: Feb. 5, 2026

(54) SEMICONDUCTOR DEVICE AND MANUFACTURING METHOD

(71) Applicant: SK hynix Inc., Icheon-si (KR)

(72) Inventors: Hwan Young KIM, Icheon-si (KR); Won Tae KOO, Icheon-si (KR)

(73) Assignee: SK hynix Inc., Icheon-si (KR)

(21) Appl. No.: 18/917,850

(22) Filed: Oct. 16, 2024

(30) Foreign Application Priority Data
Aug. 5, 2024 (KR) 10-2024-0103715

(51) Int. Cl. H10B 43/30; H01L 29/51

(52) U.S. Cl. CPC H10B 43/30; H10D 64/689

(57) ABSTRACT

A semiconductor device may include a first tunneling layer, a first charge storage layer positioned on the first tunneling layer and including an antiferroelectric material, a second charge storage layer positioned on the first charge storage layer and including a dielectric material, a second tunneling layer positioned between the first charge storage layer and the second charge storage layer, a blocking layer positioned on the second charge storage layer, and an electrode layer positioned on the blocking layer.

### CROSS-REFERENCE TO RELATED APPLICATION

This application claims priority under 35 U.S.C. § 119 to Korean Patent Application No. 10-2024-0103715, filed on Aug. 5, 2024 in the Korean Intellectual Property Office, which is incorporated herein by reference in its entirety.

### BACKGROUND

### 1. Technical Field

The present disclosure relates to a charge device and a method of manufacturing the charge device, and more particularly, to a semiconductor device and a method of manufacturing the semiconductor device.

### 2. Related Art

An integration degree of a semiconductor device is mainly determined by an area occupied by a unit memory cell. Recently, as improvement in an integration degree of a semiconductor device in which a memory cell is formed as a single layer on a substrate reaches its limit, a three-dimensional semiconductor device in which memory cells are stacked on a substrate is being proposed. In addition, various structures and manufacturing methods are being developed in order to improve operation reliability of semiconductor devices.

### SUMMARY

According to an embodiment of the present disclosure, a semiconductor device may include a first tunneling layer, a first charge storage layer disposed on the first tunneling layer and including an antiferroelectric material, a second tunneling layer disposed on the first charge storage layer, a second charge storage layer disposed on the second tunneling layer and including a dielectric material, a blocking layer disposed on the second charge storage layer, and an electrode layer disposed on the blocking layer.

According to an embodiment of the present disclosure, a semiconductor device may include a gate structure including alternately stacked insulating layers and conductive layers, a channel layer extending through the gate structure, a first tunneling layer disposed on the channel layer to surround the channel layer, a first charge storage layer, disposed to surround the first tunneling layer, and including an antiferroelectric material, a second tunneling layer disposed to surround the first charge storage layer, a second charge storage layer, disposed to surround the second tunneling layer, and including a dielectric material, and a blocking layer surrounding the second charge storage layer.

According to an embodiment of the present disclosure, a method of manufacturing a semiconductor device may include forming a first tunneling layer, forming a first charge storage layer including an antiferroelectric material on the first tunneling layer, forming a second tunneling layer on the first charge storage layer, forming a second charge storage layer including a dielectric material on the second tunneling layer, forming a blocking layer on the second charge storage layer, and forming an electrode layer on the blocking layer.

According to an embodiment of the present disclosure, a method of manufacturing a semiconductor device may include forming a stack by alternately stacking first material layers and second material layers, forming a channel hole extending through the stack, forming a blocking layer in the channel hole, forming a second charge storage layer including a dielectric material on the blocking layer, forming a second tunneling layer on the second charge storage layer, forming a first charge storage layer including an antiferroelectric material on the second tunneling layer, forming a first tunneling layer on the first charge storage layer, and forming a channel layer on the first tunneling layer.

### BRIEF DESCRIPTION OF THE DRAWINGS

FIG. 1 is a diagram illustrating a semiconductor device according to an embodiment of the present disclosure.

FIGS. 2A and 2B are diagrams illustrating a semiconductor device according to an embodiment of the present disclosure.

FIGS. 3A to 3F are diagrams illustrating an effect of a semiconductor device according to an embodiment of the present disclosure.

FIGS. 4A to 4C are diagrams illustrating a method of manufacturing a semiconductor device according to an embodiment of the present disclosure.

FIGS. 5A to 5C, 6A, and 6B are diagrams illustrating methods of manufacturing semiconductor devices according to embodiments of the present disclosure.

### DETAILED DESCRIPTION

Embodiments of the present disclosure provide a semiconductor device and a method of manufacturing the semiconductor device having a stable structure and improved characteristics.

According to the present technology, a semiconductor device having a stable structure and improved reliability may be provided. Hereinafter, embodiments according to the technical spirit of the present disclosure are described with reference to the accompanying drawings.

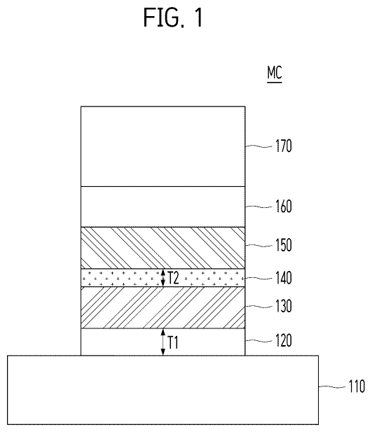

FIG. 1 is a diagram illustrating a semiconductor device according to an embodiment of the present disclosure.

Referring to FIG. 1, a semiconductor device may include a memory cell MC. The memory cell MC may include a substrate 110, a first tunneling layer 120, a first charge storage layer 130, a second tunneling layer 140, a second charge storage layer 150, a blocking layer 160, and an electrode layer 170.

The substrate 110 may include a semiconductor substrate such as a silicon substrate. The substrate 110 may include a conductive area, for example, a channel and a well doped with an impurity or a structure doped with an impurity.

The first charge storage layer 130 may be positioned on the substrate 110. A charge may be trapped in the first charge storage layer 130, and data may be stored in a bit form. For example, a state in which the charge is retained in the first charge storage layer 130 or the charge is released from the first charge storage layer 130 may be stored as data of a bit form of ‘0’, ‘1’, or a combination thereof. The first charge storage layer 130 may have a thickness of 1 to 20 nm. The first charge storage layer 130 may include an antiferroelectric material. For example, the first charge storage layer 130 may include HfO₂ including Si (hereinafter, HfO₂:Si). Here, a crystal structure of HfO₂, which is a ferroelectric material, may be changed by Si, and thus HfO₂ may become altered resulting in an antiferroelectric material.

The second charge storage layer 150 may be positioned on the first charge storage layer 130. A charge may be trapped in the second charge storage layer 150, and data may be stored in a bit form. For example, a state in which the charge is retained in the second charge storage layer 150 or the charge is released from the second charge storage layer 150 may be stored as data in a bit form of ‘0’, ‘1’, or a combination thereof. The second charge storage layer 150 may have a thickness of 1 to 20 nm. The second charge storage layer 150 may include a material different from that of the first charge storage layer 130. The second charge storage layer 150 may include a dielectric material. The second charge storage layer 150 may include a nitride. For example, the second charge storage layer 150 may include Si₃N₄.

A state in which charge is trapped in the first charge storage layer 130 and/or the second charge storage layer 150 may be referred to as a program state, and a state in which charge in the first charge storage layer 130 and/or the second charge storage layer 150 is released may be referred to as an erase state. A multi-level memory cell may be configured by changing bias applied to the memory cell MC in the form of a plurality of voltage levels to store data of a multi-bit in the first charge storage layer 130 and the second charge storage layer 150. For example, when the memory cell MC has four states and may store data of two bits per memory cell MC, data of ‘11’ may be stored by applying a first voltage level corresponding to a first state to the memory cell MC, data of ‘01’ may be stored by applying a second voltage level corresponding to a second state to the memory cell MC, data of ‘10’ may be stored by applying a third voltage level corresponding to a third state to the memory cell MC, and data of ‘00’ may be stored by applying a fourth voltage level corresponding to a fourth state to the memory cell MC. However, the bit form is not limited to ‘11, 01, 10, and 00’. In other embodiments for example, the memory cell MC may have four or more states and may have a form of two or more bits per memory cell MC.

When the first charge storage layer 130 includes HfO₂:Si, which is an antiferroelectric material, a switching speed, a program speed, and an erase speed of the memory cell MC may be improved. For example, when a bias is applied to the memory cell MC, an electric field may be concentrated at an interface between the first tunneling layer 120 and the first charge storage layer 130, and the switching speed and an operation speed of the memory cell MC may be improved. However, when the first charge storage layer 130 includes an antiferroelectric material, an amount of a charge trapped in the first charge storage layer 130 may not be sufficient to implement a multi-level memory cell. In other words, because an amount of charge trapped in the memory cell MC is insufficient, distinguishing states required for implementing a multi-level memory cell MC may not be possible.

When the first charge storage layer 130 includes Si₃N₄, which is a dielectric material, the amount of charge trapped in the first charge storage layer 130 may be secured in the necessary amounts, but the states required for implementing a multi-level memory cell may not be clearly distinguished. Therefore, when the first charge storage layer 130 includes a dielectric material, the switching speed and the operation speed of the memory cell MC may be relatively slow compared to a case where the first charge storage layer 130 includes an antiferroelectric material.

According to an embodiment of the present disclosure, the memory cell MC may include both of a first charge storage layer 130 including an antiferroelectric material and a second charge storage layer 150 including a dielectric material. In other words, as the first charge storage layer 130 includes HfO₂:Si, the switching speed and the operation speed of the memory cell MC may be improved, and as the second charge storage layer 150 includes Si₃N₄, because the amount of charge trapped in the memory cell MC may be sufficiently secured to implement a multi-level memory cell. Therefore, according to an embodiment of the present disclosure, the switching speed and the operation speed of the memory cell MC may be improved, and as the amount of charge trapped in the memory cell MC may be sufficiently secured, an improved multi-level memory cell may be implemented. In addition, as the improved multi-level memory cell is implemented, because an energy state that may represent an operation may be variously implemented, an improved computing-in-memory (CIM) may be implemented.

The first tunneling layer 120 may be positioned on the substrate 110. The first tunneling layer 120 may be positioned between the substrate 110 and the first charge storage layer 130. The first tunneling layer 120 may be used as a path through which a charge in the substrate 110 tunnels to the first charge storage layer 130 when a bias is applied to the memory cell MC.

The first tunneling layer 120 may have a first thickness T1, and the first thickness T1 may be 1 to 5 nm. When the first tunneling layer 120 exceeds 5 nm, the charge in the substrate 110 may not tunnel to the first charge storage layer 130, or the amount of tunneling may be reduced. The first tunneling layer 120 may include an oxide. For example, the first tunneling layer 120 may include SiO₂.

The second tunneling layer 140 may be positioned on the first charge storage layer 130. The second tunneling layer 140 may be positioned between the first charge storage layer 130 and the second charge storage layer 150.

The second tunneling layer 140 may be used as a buffer layer between the first charge storage layer 130 and the second charge storage layer 150. For example, when the second tunneling layer 140 is omitted in a process of manufacturing a semiconductor device, the second charge storage layer 150 may be directly formed on the first charge storage layer 130. In this case, the first charge storage layer 130 or the second charge storage layer 150 may be damaged due to differences in crystal structure between the first charge storage layer 130 including an antiferroelectric material and the second charge storage layer 150 including a dielectric material.

In addition, without the second tunneling layer 140, in a process of programming or erasing the memory cell MC, a material included in the first charge storage layer 130 may diffuse into the second charge storage layer 150, and a material included in the second charge storage layer 150 may diffuse into the first charge storage layer 130. When this process is repeated, the memory cell MC may deteriorate. According to an embodiment of the present disclosure, by forming the second tunneling layer 140 between the first charge storage layer 130 and the second charge storage layer 150, damage to the first charge storage layer 130 and the second charge storage layer 150 may be prevented or reduced, and deterioration of the memory cell MC may be slowed.

The second tunneling layer 140 may have a second thickness T2, and the second thickness T2 may be substantially equal to or different from the first thickness T1 of the first tunneling layer 120. The second thickness T2 may be less than the first thickness T1, and may be 1 to 3 nm. The second tunneling layer 140 may be relatively thinner compared to the first tunneling layer 120, and a charge may be tunnel relatively easily between the first charge storage layer 130 and the second charge storage layer 150. In other words, the second tunneling layer 140 may serve as a buffer layer between the first charge storage layer 130 and the second charge storage layer 150, and may have a thin thickness so that tunneling of a charge is possible and not impeded. The second tunneling layer 140 may include a material substantially the same to or different from that of the first tunneling layer 120. The second tunneling layer 140 may include an oxide. For example, the second tunneling layer 140 may include SiO₂.

The blocking layer 160 may be positioned on the second charge storage layer 150. For example, the blocking layer 160 may be positioned between the second charge storage layer 150 and the electrode layer 170. The blocking layer 160 may have a thickness of 1 to 20 nm. The blocking layer 160 may block movement of a charge between the second charge storage layer 150 and the electrode layer 170. The blocking layer 160 may include a high dielectric constant material. For example, the blocking layer 160 may include Al₂O₃.

The electrode layer 170 may be positioned on the blocking layer 160. The electrode layer 170 may include a conductive material. The electrode layer 170 may include a metal nitride. For example, the electrode layer 170 may include TiN or the like.

For reference, although not illustrated in FIG. 1, a semiconductor device may further include first conductive lines and second conductive lines positioned on the first conductive lines. Here, the first conductive lines may extend in a first direction, and the second conductive lines may extend in a second direction intersecting the first direction. The memory cells MC may be positioned in an area where the first conductive lines and the second conductive lines intersect. For example, memory cells MC may be positioned between the first conductive line and the second conductive line, and the memory cells MC may be arranged to be connected in parallel in a horizontal direction. As another example, stacked memory cells MC may be positioned between the first conductive line and the second conductive line, and the memory cells MC may be arranged to be connected in series in a vertical direction.

According to the structure described above, a memory cell MC may include a first charge storage layer 130 including an antiferroelectric material and a second charge storage layer 150 including a dielectric material. Therefore, the switching speed and the operation speed of the memory cell MC may be improved, and an improved multi-level memory cell may be implemented with enough charge trapped in the memory cell MC.

In addition, the memory cell MC may include a second tunneling layer 140. The second tunneling layer 140 may be positioned between the first charge storage layer 130 and the second charge storage layer 150, may serve as the buffer layer, and may be used as a layer through which a charge tunnels. The second tunneling layer 140 may prevent the first charge storage layer 130 or the second charge storage layer 150 from being damaged in the process of manufacturing the semiconductor device, and may reduce the speed at which the memory cell MC deteriorates.

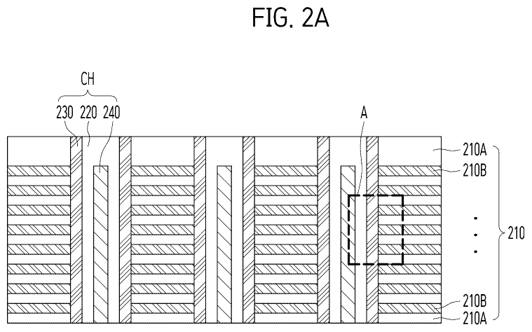

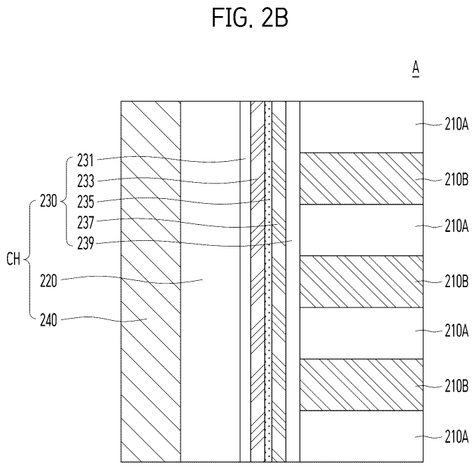

FIGS. 2A and 2B are diagrams illustrating a semiconductor device according to an embodiment of the present disclosure. FIG. 2A may be a cross-sectional view, and FIG. 2B may be an enlarged view of area A in FIG. 2A. Hereinafter, content that overlaps with content previously described above is omitted for clarity.

Referring to FIGS. 2A and 2B, a semiconductor device may include a gate structure 210 and a channel structure CH.

The gate structure 210 may include alternately stacked insulating layers 210A and conductive layers 210B. The insulating layers 210A may include an insulating material such as an oxide, and the conductive layers 210B may include a conductive material such as tungsten, molybdenum, or polysilicon. The conductive layers 210B may be a gate line such as a source selection line, a word line, or a drain selection line. A source selection transistor, a memory cell, or a drain selection transistor may be positioned in an area where the channel structures CH and the conductive layers 210B intersect. For example, at least one source selection transistor, a plurality of memory cells, and at least one drain selection transistor stacked along the channel structure CH may configure one memory string.

The channel structure CH may extend through the gate structure 210. The channel structure CH may include a channel layer 220 and a memory layer 230 surrounding the channel layer 220. The channel structure CH may further include an insulating core 240 positioned in the channel layer 220. Here, the channel layer 220 may include a semiconductor material such as polysilicon or germanium. The insulating core 240 may include an insulating material such as an oxide.

Referring to FIG. 2B, the memory layer 230 may include a first tunneling layer 231, a first charge storage layer 233, a second tunneling layer 235, a second charge storage layer 237, and a blocking layer 239. Here, the first tunneling layer 231, the first charge storage layer 233, the second tunneling layer 235, the second charge storage layer 237, and the blocking layer 239 may be sequentially layered to surround the channel layer 220.

The first charge storage layer 233 may surround the channel layer 220 and may include an antiferroelectric material. Here, the antiferroelectric material may be HfO₂ including Si (hereinafter, HfO₂:Si). The second charge storage layer 237 may surround the first charge storage layer 233 and may include a dielectric material. Here, the dielectric material may be Si₃N₄. Charge may be trapped in the first charge storage layer 233 and the second charge storage layer 237, and data may be stored in a bit form. The second charge storage layer 237 may have substantially the same thickness as the first charge storage layer 233.

According to an embodiment of the present disclosure, both of the first charge storage layer 233 including HfO₂:Si, which is an antiferroelectric material, and the second charge storage layer 237 including a dielectric material may be included. As a result, the switching speed and the operation speed of the memory cell may be improved, and an improved multi-level memory cell may be implemented by sufficiently retaining an amount of charge in the memory cell.

The first tunneling layer 231 may be positioned between the channel layer 220 and the first charge storage layer 233. The second tunneling layer 235 may be positioned between the first charge storage layer 233 and the second charge storage layer 237. The first tunneling layer 231 or the second tunneling layer 235 may include an oxide. For example, the first tunneling layer 231 or the second tunneling layer 235 may include SiO₂.

The first tunneling layer 231 may be used as a path through which a charge in the channel layer 220 tunnels to the first charge storage layer 233 when a bias is applied to the conductive layers 210B. The second tunneling layer 235 may be used as a buffer layer between the first charge storage layer 233 and the second charge storage layer 237. For example, by forming the second tunneling layer 235 between the first charge storage layer 233 and the second charge storage layer 237, damage to the first charge storage layer 233 or the second charge storage layer 237 may be prevented or reduced in a process of forming the semiconductor device, and a speed at which the memory cell deteriorates may be reduced.

The second tunneling layer 235 may have a relatively thinner thickness compared to the first tunneling layer 231. The second tunneling layer 235 may serve as a buffer layer between the first charge storage layer 233 and the second charge storage layer 237, and may have a thickness that allows charge tunneling.

The blocking layer 239 may surround the second charge storage layer 237. For example, the blocking layer 239 may be positioned between the second charge storage layer 237 and the conductive layers 210B. The blocking layer 239 may block movement of charge between the second charge storage layer 237 and the conductive layers 210B. The blocking layer 239 may include a high dielectric constant material. For example, the blocking layer 239 may include Al₂O₃.

According to the structure described above, memory cells may be positioned in an area where the channel structures CH and the conductive layers 210B intersect. Stacked memory cells may share the first tunneling layer 231, the first charge storage layer 233, the second tunneling layer 235, the second charge storage layer 237, and the blocking layer 239.

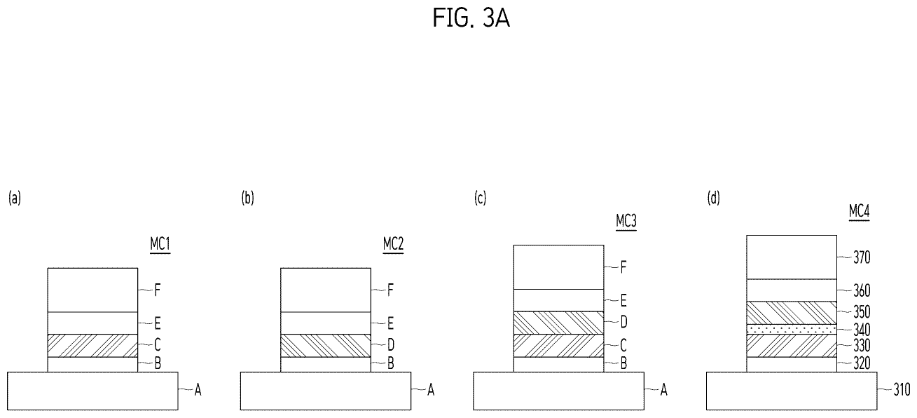

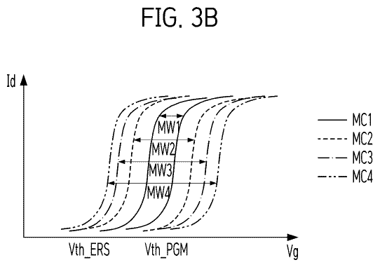

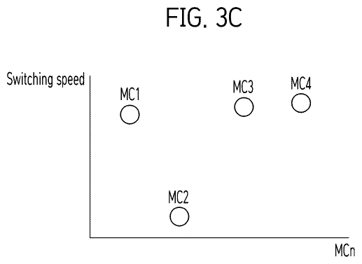

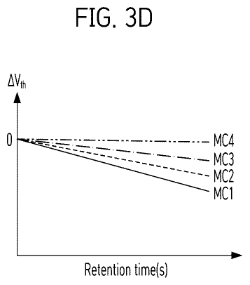

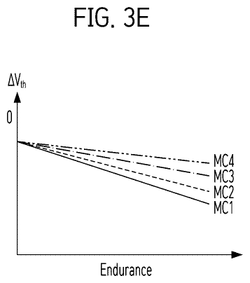

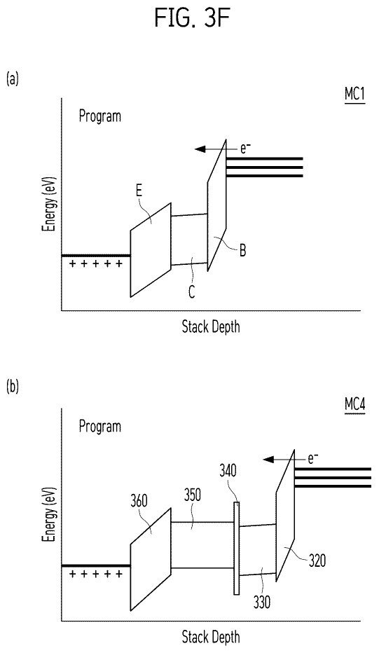

FIGS. 3A to 3F are diagrams illustrating an effect of a semiconductor device according to an embodiment of the present disclosure. Hereinafter, content that overlaps with content previously described above is omitted for clarity.

Referring to (a) of FIG. 3A, a first memory cell MC1 includes a substrate A, a first tunneling layer B, a first charge storage layer C, a blocking layer E, and an electrode layer F. For example, the first memory cell MC1 includes the substrate A, the first tunneling layer B, the first charge storage layer C, the blocking layer E, and the electrode layer F that are sequentially stacked. Here, the first charge storage layer C includes a dielectric material.

Referring to (b) of FIG. 3A, a second memory cell MC2 has a structure similar to that of the first memory cell MC1, and includes a second charge storage layer D instead of the first charge storage layer C of the first memory cell MC1. Here, the second charge storage layer D includes an antiferroelectric material.

Referring to (c) of FIG. 3A, a third memory cell MC3 includes both of the first charge storage layer C of the first memory cell MC1 and the second charge storage layer D of the second memory cell MC2. Here, the second charge storage layer D is positioned on the first charge storage layer C.

Referring to (d) of FIG. 3A, a fourth memory cell MC4 further includes a second tunneling layer 340 positioned between the first charge storage layer 330 and the second charge storage layer 350 in the third memory cell MC3. Here, the second tunneling layer 340 includes SiO₂.

Referring to FIG. 3B, an x-axis means a threshold voltage, and a y-axis means a current amount. Referring to FIG. 3B, a memory window MW of the first memory cell MC1, the second memory cell MC2, the third memory cell MC3, and the fourth memory cell MC4 may be compared. Here, the memory window MW may mean a difference between a threshold voltage Vth_PGM of programmed memory cells MC1, MC2, MC3, and MC4 and a threshold voltage Vth_ERS of erased memory cells MC1, MC2, MC3, and MC4, respectively. In other words, the memory window MW may mean a charge trap capacity as a total space for a level of voltage used to implement a multi-level memory cell.

The first memory cell MC1 includes a first charge storage layer 330 including an antiferroelectric material, and the second memory cell MC2 includes a second charge storage layer 350 including a dielectric material. Here, the antiferroelectric material may not provide a sufficient charge trap space, and the dielectric material may provide a sufficient charge trap space compared to the antiferroelectric material. Therefore, the second memory cell MC2 may have a second memory window MW2 greater than that of a first memory window MW1 of the first memory cell MC1.

The third memory cell MC3 includes both of the first charge storage layer 330 and the second charge storage layer 350. Here, in the third memory cell MC3, charge may be additionally trapped at an interface between the first charge storage layer 330 and the second charge storage layer 350. Therefore, the third memory cell MC3 may have a third memory window MW3 greater than a sum of the first memory window MW1 and the second memory window MW2.

The fourth memory cell MC4 further includes the second tunneling layer 340 between the first charge storage layer 330 and the second charge storage layer 350. Charge may be trapped at an interface between the first charge storage layer 330 and the second tunneling layer 340 and at an interface between the second tunneling layer 340 and the second charge storage layer 350. Therefore, because charge may be trapped at more interfaces in the fourth memory cell MC4 than in the third memory cell MC3, the fourth memory cell MC4 may have a fourth memory window MW4 greater than the third memory window MC3.

Referring to FIG. 3C, an x-axis means a number of a memory cell, and a y-axis means a switching speed of the memory cell. [see comment] Referring to FIG. 3C, switching speeds of the first memory cell MC1, the second memory cell MC2, the third memory cell MC3, and the fourth memory cell MC4 may be compared.

When a bias is applied to the first memory cell MC1 and the second memory cell MC2, an antiferroelectric material may concentrate an electric field on a surface and provide a relatively fast switching speed compared to a dielectric material. Therefore, the first memory cell MC1 including the antiferroelectric material may have a fast switching speed compared to the second memory cell MC2 including the dielectric material.

The third memory cell MC3 and the fourth memory cell MC4 include both of the first charge storage layer 330 and the second charge storage layer 350. Therefore, the third memory cell MC3 and the fourth memory cell MC4 may have a switching speed similar to that of the first memory cell MC1 and may have a faster switching speed compared to the second memory cell MC2.

Referring to FIG. 3D, an x-axis means a data retention time, and a y-axis means a change amount of a threshold voltage. Referring to FIG. 3D, the data retention times of the first memory cell MC1, the second memory cell MC2, the third memory cell MC3, and the fourth memory cell MC4 may be compared.

The first charge storage layer 330 or the second charge storage layer 350 may generate an internal electric field while retaining data. Here, the charges trapped in the first charge storage layer 330 or the second charge storage layer 350 by the internal electric field of the first charge storage layer 330 or the second charge storage layer 350 may be released through the first tunneling layer 320 or the blocking layer 360.

The antiferroelectric material may provide an environment in which a charge is tunneled relatively fast compared to the dielectric material. The charges trapped in the first memory cell MC1 including the antiferroelectric material may be released faster compared to the charges trapped in the second memory cell MC2 including the dielectric material. Therefore, the data retention time of the second memory cell MC2 may be longer than that of the first memory cell MC1.

The third memory cell MC3 includes the first charge storage layer 330 including the antiferroelectric material and the second charge storage layer 350 including the dielectric material. In a state in which the third memory cell MC3 does not operate, the charges trapped in the first charge storage layer 330 and the second charge storage layer 350 may be distributed and exchanged to both across an interface between the first charge storage layer 330 and the second charge storage layer 350. As a result, the internal electric field of the first charge storage layer 330 or the second charge storage layer 350 may be reduced. Therefore, the data retention time of the third memory cell MC3 may be longer than that of the second memory cell MC2.

The fourth memory cell MC4 may further include the second tunneling layer 340 between the first charge storage layer 330 and the second charge storage layer 350. In a state in which the fourth memory cell MC4 does not operate, the charges trapped in the first charge storage layer 330 and the second charge storage layer 350 may be distributed to both sides based on an interface between the first charge storage layer 330 and the second tunneling layer 340 or an interface between the second tunneling layer 340 and the second charge storage layer 350. In other words, in the fourth memory cell MC4, the trapped charges may be distributed in the second tunneling layer 340. As a result, the internal electric field of the first charge storage layer 330 and the second charge storage layer 350 may be relatively reduced. Therefore, the data retention time of the fourth memory cell MC4 may be longer than that of the third memory cell MC3.

Referring to FIG. 3E, an x-axis means endurance of the memory cells, and a y-axis means a change amount of a threshold voltage. Referring to FIG. 3E, deterioration speeds of the first memory cell MC1, the second memory cell MC2, the third memory cell MC3, and the fourth memory cell MC4 may be compared.

The memory cells MC1, MC2, MC3, and MC4 may deteriorate when repeatedly performing a program operation or an erase operation. When the memory cells include antiferroelectric material, the program operation or the erase operation may be performed with a relatively small threshold voltage compared to a case where the memory cells include dielectric material. Memory cells with antiferroelectric material may deteriorate relatively slowly.

When repeatedly performing program operations or erase operations in the third memory cell MC3, the third memory cell MC3 may be damaged and deteriorate due to material spreading between the first charge storage layer 330 and the second charge storage layer 350. In addition, because the third memory cell MC3 is formed so that the first charge storage layer 330 and the second charge storage layer 350 are in contact, the first charge storage layer 330 or the second charge storage layer 350 may be damaged due to a difference in relative crystal structures, and damage may be accelerated when the program operations or the erase operations are repeated.

The fourth memory cell MC4 further includes the second tunneling layer 340 between the first charge storage layer 330 and the second charge storage layer 350. The second tunneling layer 340 may be used as a buffer layer between the first charge storage layer 330 and the second charge storage layer 350. For example, the second tunneling layer 340 of the fourth memory cell MC4 may prevent or reduce mutual diffusion of material included in the first charge storage layer 330 and the second charge storage layer 350 when the fourth memory cell MC4 is operating. In addition, the second tunneling layer 340 may prevent or reduce damage to the first charge storage layer 330 or the second charge storage layer 350 due to a difference in a crystal structure between the first charge storage layer 330 and the second charge storage layer 350. Therefore, the fourth memory cell MC4 may be damaged relatively less and deteriorate relatively slowly compared to the third memory cell MC3.

Referring to FIG. 3F, an x-axis means a stack depth of the memory cells, and a y-axis means energy size. Referring to FIG. 3F, charge trap capacities of the first memory cell MC1 and the fourth memory cell MC4 may be compared.

Referring to (a) of FIG. 3F, when a bias is applied to the first memory cell MC1, charges may move through the first tunneling layer B, the first charge storage layer C, and the blocking layer E. In this process, charges may be trapped in the first charge storage layer C.

Referring to (b) of FIG. 3F, when a bias is applied to the fourth memory cell MC4, charges may be move through the first tunneling layer 320, the first charge storage layer 330, the second tunneling layer 340, the second charge storage layer 350, and the blocking layer 360. In this process, charges may be trapped in the first charge storage layer 330 and the second charge storage layer 350. In other words, because the fourth memory cell MC4 may trap charges in the first charge storage layer 330 and the second charge storage layer 350, the fourth memory cell MC4 may have a charge trap capacity that is greater than that of the first memory cell MC1.

According to the structure described above, the fourth memory cell MC4 includes the first charge storage layer 330 including an antiferroelectric material and the second charge storage layer 350 including a dielectric material. Therefore, the fourth memory cell MC4 may secure enough charge trap capacity and improve an operation speed in implementing a multi-level memory cell.

In addition, the fourth memory cell MC4 further includes the second tunneling layer 340 positioned between the first charge storage layer 330 and the second charge storage layer 350. Therefore, the data retention time of the fourth memory cell MC4 may be relative longer and deterioration of the fourth memory cell MC4 may be slower compared to the memory cells MC1, MC2, and MC3, which do not include the second tunneling layer 340.

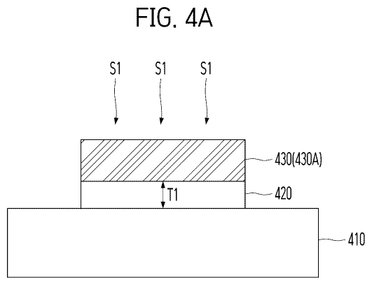

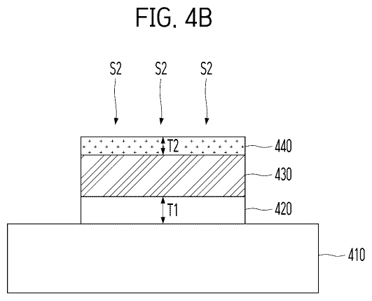

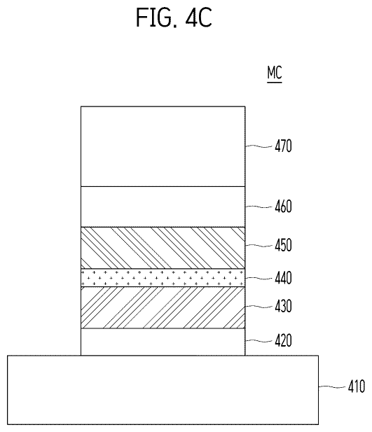

FIGS. 4A to 4C are diagrams illustrating a method of manufacturing a semiconductor device according to an embodiment of the present disclosure. Hereinafter, content that overlaps with content previously described above is omitted for clarity.

Referring to FIG. 4A, a first tunneling layer 420 may be formed. For example, the first tunneling layer 420 may be formed on a substrate 410. Here, the substrate 410 may include a semiconductor substrate such as a silicon substrate.

The first tunneling layer 420 may be used as a path through which a charge in the substrate 410 tunnels to a first charge storage layer 430 when a bias is applied to a memory cell. The first tunneling layer 420 may be formed in a first thickness T1. Here, the first thickness T1 may be 1 to 5 nm. When the first tunneling layer 420 exceeds 5 nm, the charge in the substrate 410 may not be able to tunnel to the first charge storage layer 430, or an amount of tunneling to the first charge storage layer 430 may be reduced. The first tunneling layer 420 may include an oxide. For example, the first tunneling layer 420 may include SiO₂.

Subsequently, a first charge storage layer 430 including an antiferroelectric material may be formed on the first tunneling layer 420. Charge may be trapped in the first charge storage layer 430, and data may be stored in a bit form. The first charge storage layer 430 may be formed in a thickness of 1 to 20 nm.

The first charge storage layer 430 may be formed using a spread method or may be formed using a deposition method. However, the disclosure is not limited thereto, and the first charge storage layer 430 including the antiferroelectric material may be formed on the first tunneling layer 420 in various methods.

For example, a preliminary first charge storage layer 430A may be formed on the first tunneling layer 420. Here, the preliminary first charge storage layer 430A may include a ferroelectric material. For example, the preliminary first charge storage layer 430A may include HfO₂. Subsequently, a first heat treatment S1 may be performed. Through the first heat treatment S1, a material included in the first tunneling layer 420 may be diffuse into the preliminary first charge storage layer 430A to form the first charge storage layer 430 including antiferroelectric material. For example, Si included in the first tunneling layer 420 may spread into the preliminary first charge storage layer 430A to form HfO₂ including Si (hereinafter, HfO₂:Si). In other words, a crystal structure of HfO₂, which is a ferroelectric material may be changed by Si, and thus HfO₂ may altered resulting in an antiferroelectric material.

As another example, the first charge storage layer 430 including the antiferroelectric material may be deposited on the first tunneling layer 420. In other words, the first charge storage layer 430 including HfO₂:Si may be directly deposited on the first tunneling layer 420.

Referring to FIG. 4B, a second tunneling layer 440 may be formed on the first charge storage layer 430. The second tunneling layer 440 may be formed in a second thickness T2, which is thinner than the first thickness T1 of the first tunneling layer 420. Here, the second thickness T2 may be 1 to 3 nm. The second tunneling layer 440 may include a material substantially equal to or different from that of the first tunneling layer 420. The second tunneling layer 440 may include an oxide. For example, the second tunneling layer 440 may include SiO₂.

Subsequently, a second heat treatment S2 may be performed. The second tunneling layer 440 may be crystallized through the second heat treatment S2. Here, the crystallized second tunneling layer 440 may be used as a buffer layer. For example, when crystallizing the second tunneling layer 440, reaction of the second tunneling layer 440 and a second charge storage layer, and formation of a new layer, may be prevented or minimized in a process of forming the second charge storage layer on the second tunneling layer 440. Therefore, the second tunneling layer 440 may serve as a buffer layer, and may be formed in a thickness so that tunneling of a charge through the layer is possible.

Referring to FIG. 4C, a second charge storage layer 450 including a dielectric material may be formed on the second tunneling layer 440. Charge may be trapped in the second charge storage layer 450, and data may be stored in a bit form. The second charge storage layer 450 may have substantially the same thickness as the first charge storage layer 430. For example, the second charge storage layer 450 may be formed in a thickness of 1 to 20 nm. The second charge storage layer 450 may include a nitride. For example, the second charge storage layer 450 may include Si₃N₄.

In a process of forming the second charge storage layer 450, the second tunneling layer 440 may be used as a buffer layer. For example, when the second charge storage layer 450 is directly formed on the first charge storage layer 430, without forming the second tunneling layer 440, the first charge storage layer 430 or the second charge storage layer 450 may be damaged due to a difference in crystal structure between the first charge storage layer 430 including an antiferroelectric material and the second charge storage layer 450 including a dielectric material. Therefore, according to an embodiment of the present disclosure, by forming the second tunneling layer 440, damage to the first charge storage layer 430 or the second charge storage layer 450 may be prevented or reduced.

Subsequently, a blocking layer 460 may be formed on the second charge storage layer 450. The blocking layer 460 may have a thickness of 1 to 20 nm. The blocking layer 460 may block movement of charges between the second charge storage layer 450 and the electrode layer. The blocking layer 460 may include a high dielectric constant material. For example, the blocking layer 460 may include Al₂O₃.

Subsequently, an electrode layer 470 may be formed on the blocking layer 460. The electrode layer 470 may include a conductive material. The electrode layer 470 may include a metal nitride. For example, the electrode layer 470 may include TIN or the like. Accordingly, a memory cell MC including the substrate 410, the first tunneling layer 420, the first charge storage layer 430, the second tunneling layer 440, the second charge storage layer 450, the blocking layer 460, and the electrode layer 470 may be formed.

In a process of programming or erasing the memory cell MC, material diffusion may occur between the first charge storage layer 430 and the second charge storage layer 450, and as a result the memory cell MC may deteriorate. According to an embodiment of the present disclosure, by forming the second tunneling layer 440, mutual spread of material included in the first charge storage layer 430 and the second charge storage layer 450 may be prevented or reduced, and the rate of deterioration of memory cell MC may be reduced.

In addition, according to an embodiment of the present disclosure, the memory cell MC may include both of the first charge storage layer 430 including the antiferroelectric material and the second charge storage layer 450 including the dielectric material. As a result, the switching speed and the operation speed of the memory cell MC may be improved, and a multi-level memory cell may be implemented with sufficient charge trapped in the memory cell MC.

According to the manufacturing methods described above, the first charge storage layer 430 including the antiferroelectric material may be formed on the first tunneling layer 420. For example, the first charge storage layer 430 including HfO₂:Si, which is the antiferroelectric material may be formed by diffusion of Si of the first tunneling layer 420 into the preliminary first charge storage layer 430A including HfO₂, which is the ferroelectric material, through the first heat treatment S1. Alternatively, the first charge storage layer 430 including the antiferroelectric material may be directly deposited on the first tunneling layer 420.

The second tunneling layer 440 may be formed between the first charge storage layer 430 and the second charge storage layer 450. The second tunneling layer 440 may serve as a buffer layer. For example, the second tunneling layer 440 may prevent damage due to a difference in crystal structure between the first charge storage layer 430 and the second charge storage layer 450, and may prevent materials included in the first charge storage layer 430 and the second charge storage layer 450 from being exchanged when repeatedly operating the memory cell MC, thereby reducing the deterioration rate of the memory cell MC.

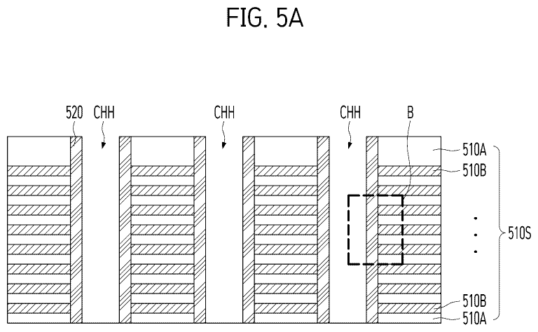

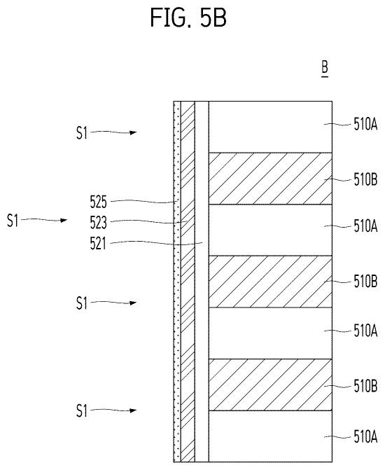

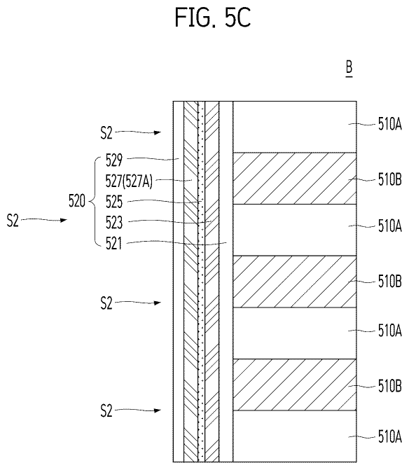

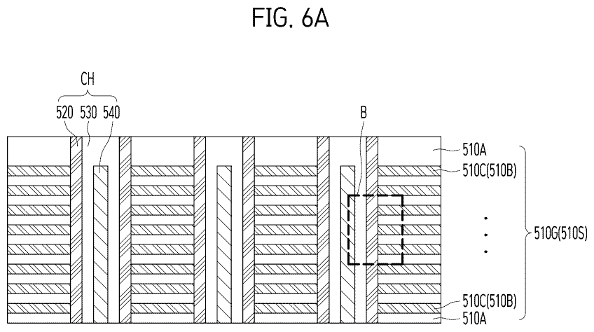

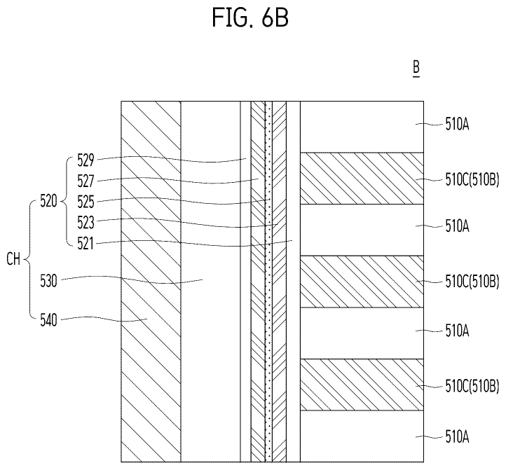

FIGS. 5A to 5C, 6A, and 6B are diagrams illustrating methods of manufacturing semiconductor devices according to embodiments of the present disclosure. FIGS. 5A and 6A may be cross-sectional views, and FIGS. 5B, 5C, and 6B may be enlarged views of area B in FIGS. 5A and 6A. Hereinafter, a content overlapping the content described above is omitted.

Referring to FIGS. 5A to 5C, a stack 510S may be formed by alternately stacking first material layers 510A and second material layers 510B. The first material layers 510A may include an insulating material such as an oxide, and the second material layers 510B may include a sacrificial material such as a nitride.

Subsequently, a channel hole CHH extending through the stack 510S may be formed. Subsequently, a blocking layer 521 may be formed in the channel hole CHH. The blocking layer 521 may block movement of a charge between a second charge storage layer 523 and conductive material layers of a stack or a gate. The blocking layer 521 may include a high dielectric constant material. For example, the blocking layer 521 may include Al₂O₃.

Subsequently, the second charge storage layer 523 including a dielectric material may be formed on the blocking layer 521. Charge may be trapped in the second charge storage layer 523, and data may be stored in a bit form. The second charge storage layer 523 may include a nitride. The second charge storage layer 523 may include Si₃N₄.

Subsequently, a second tunneling layer 525 may be formed on the second charge storage layer 523. The second tunneling layer 525 may be formed in a relatively thinner thickness compared to a first tunneling layer 529. The second tunneling layer 525 may include an oxide. For example, the second tunneling layer 525 may include SiO₂.

Subsequently, a first heat treatment S1 may be performed. The second tunneling layer 525 may be crystallized through the first heat treatment S1. Here, the crystallized second tunneling layer 525 may be used as a buffer layer. For example, when crystallizing the second tunneling layer 525, reaction of the second tunneling layer 525 and the second charge storage layer 523, and formation of a new layer, may be prevented or minimized in a process of forming the second charge storage layer 523 on the second tunneling layer 525. Therefore, the second tunneling layer 525 may serve as a buffer layer and may be formed in a thickness that is still thin enough to allow charge tunneling.

Subsequently, the first charge storage layer 527 including an antiferroelectric material may be formed on the second tunneling layer 525. For example, the first charge storage layer 527 may be deposited on the second tunneling layer 525. In other words, HfO₂ including Si may be formed in the second tunneling layer 525. Charge may be trapped in the first charge storage layer 527, and data may be stored in a bit form. The first charge storage layer 527 may be formed with substantially the same thickness as the second charge storage layer 523.

In a process of forming the first charge storage layer 527, the second tunneling layer 525 may be used as a buffer layer. For example, when the first charge storage layer 527 is directly formed on the second charge storage layer 523 without forming the second tunneling layer 525, the first charge storage layer 527 or the second charge storage layer 523 may be damaged due to a difference in crystal structure between the first charge storage layer 527 including an antiferroelectric material and the second charge storage layer 523 including a dielectric material. Therefore, according to embodiments of the present disclosure, by forming the second tunneling layer 525, damage to the first charge storage layer 527 and the second charge storage layer 523 may be prevented or reduced.

Subsequently, a first tunneling layer 529 may be formed in the first charge storage layer 527. Accordingly, a memory layer 520 including the first tunneling layer 529, the first charge storage layer 527, the second tunneling layer 525, the second charge storage layer 523, and the blocking layer 521 may be formed. The first tunneling layer 529 may be used as a path through which charges from a channel layer tunnel to the first charge storage layer 527 when a bias is applied to the conductive material layers of a stack or a gate. The first tunneling layer 529 may include an oxide. For example, the first tunneling layer 529 may include SiO₂.

Meanwhile, the first charge storage layer 527 may be formed in various methods in addition to a deposition method. For example, a preliminary first charge storage layer 527A may be formed on the second tunneling layer 525. Here, the preliminary first charge storage layer 527A may include a ferroelectric material. For example, the preliminary first charge storage layer 527A may include HfO₂. Subsequently, a second heat treatment S2 may be performed. The first charge storage layer 527 including an antiferroelectric material may be formed a material included in the first tunneling layer 529 diffuses into the preliminary first charge storage layer 527A through the second heat treatment S2. For example, HfO₂ including Si (hereinafter, HfO₂:Si) may be formed by spreading Si included in the first tunneling layer 529 into the preliminary first charge storage layer 527A. In other words, a crystal structure of HfO₂, which is the ferroelectric material altered with the introduction of Si, and thus HfO₂ may altered resulting in an antiferroelectric material.

Referring to FIGS. 6A and 6B, a channel layer 530 may be formed on a memory layer 520. For example, the channel layer 530 may be formed on the first tunneling layer 529. Subsequently, an insulating core 540 may be formed on the channel layer 530. Accordingly, a channel structure CH including the memory layer 520, the channel layer 530, and the insulating core 540 may be formed. The channel layer 530 may include a semiconductor material such as polysilicon or germanium, and the insulating core 540 may include an insulating material such as an oxide.

Subsequently, the second material layers 510B may be replaced with third material layers 510C through a slit (not shown). For example, after removing the second material layers 510B through the slit, the third material layers 510C may be deposited. Here, the third material layers 510C may include a conductive material. Accordingly, a gate structure 510G including the first material layers 510A and the third material layers 510C alternately stacked may be formed. Meanwhile, when the second material layers 510B include a conductive material, a process of replacing the second material layers 510B with the third material layers 510C may be omitted, and the stack 510S may be used as the gate structure 510G.

According to manufacturing methods described above, memory cells may be positioned in an area where channel structures CH and third material layers 510C intersect. The stacked memory cells may share the first tunneling layer 529, the first charge storage layer 527, the second tunneling layer 525, the second charge storage layer 523, and the blocking layer 521.

Although embodiments according to the technical spirit of the present disclosure have been described with reference to the accompanying drawings, this is only for describing embodiments according to the concepts of the present disclosure, and the present disclosure is not limited to the above-described embodiments. In the scope of the technical spirit of the present disclosure described in the claims, various forms of substitution, modification, and change of the embodiments will be possible by those skilled in the art to which the present disclosure belongs, and these also belong to the scope of the present disclosure.

What is claimed is:

1. A semiconductor device comprising:
a first tunneling layer;
a first charge storage layer disposed on the first tunneling layer and including an antiferroelectric material;
a second tunneling layer disposed on the first charge storage layer;
a second charge storage layer disposed on the second tunneling layer and including a dielectric material;
a blocking layer disposed on the second charge storage layer; and
an electrode layer disposed on the blocking layer.

2. The semiconductor device according to claim 1, wherein the first charge storage layer includes HfO₂ including Si and,
the second charge storage layer includes Si₃N₄.

3. The semiconductor device according to claim 1, wherein the second tunneling layer includes an oxide.

4. The semiconductor device according to claim 3, wherein the second tunneling layer includes SiO₂.

5. The semiconductor device according to claim 1, wherein the first tunneling layer has a first thickness, and the second tunneling layer has a second thickness that is less than the first thickness.

6. A semiconductor device comprising:
a gate structure including alternately stacked insulating layers and conductive layers;
a channel layer extending through the gate structure;
a first tunneling layer disposed on the channel layer to surround the channel layer;
a first charge storage layer, disposed to surround the first tunneling layer, and including an antiferroelectric material;
a second tunneling layer disposed to surround the first charge storage layer; and
a second charge storage layer, disposed to surround the second tunneling layer, and including a dielectric material; and
a blocking layer surrounding the second charge storage layer.

7. The semiconductor device according to claim 6, wherein the first charge storage layer includes HfO₂ including Si, and
the second charge storage layer includes Si₃N₄.

8. The semiconductor device according to claim 6, wherein the second tunneling layer includes an oxide.

9. The semiconductor device according to claim 8, wherein the second tunneling layer includes SiO₂.

10. The semiconductor device according to claim 6, wherein the second tunneling layer is thinner than the first tunneling layer.
